(19) United States
(12) Patent Application Publication
(10) Pub. No.: US 2008/0180125 A1
(43) Pub. Date: Jul. 31, 2008

(54) Contact Probe And Socket For Testing Semiconductor Chips

(75) Inventor: Chae Yoon Lee, Busan (KR)

Correspondence Address: HYUN JONG PARK, 41 WHITE BIRCH ROAD, REDDING, CT, 06896-2209, US

(73) Assignee: Leeno Industrial Inc., Gangseo-Gu (KR)

(21) Appl. No.: 11/865,040

(22) Filed: Sep. 30, 2007

(30) Foreign Application Priority Data
Jan. 25, 2007 (KR) 10-2007-0007929
May 16, 2007 (KR) 10-2007-0047360

(51) Int. Cl. G01R 1/067

(52) U.S. Cl. 324/761

(57) ABSTRACT

A contact probe and a socket for testing semiconductor chips are provided with a simple structure, so that they can be easily manufactured, and can reduce a signal path not only to improve test reliability but also remarkably reduce the dimensions of test equipment. The contact probe comprises: a nonconductive elastic plate having main through-holes corresponding to contact terminals of a test target; plungers coupled on upper sides of the main through-holes, each having a plunger head that is elastically supported by the elastic plate and a plunger body that extends downwards from the center of the plunger head; and contact pins coupled on lower sides of the main through-holes, each having a receiving hole contacting the plunger body of each plunger at a center thereof. Thus, the contact probe employs a simple structure capable of coupling the plungers to the nonconductive elastic plate and elastically supporting the plungers, so that they can be easily manufactured, improve the signal pass of test electric current to secure test reliability, and be manufactured at a subminiature size suitable for equipment for testing semiconductor chips, which are gradually becoming complicated due to technical development.

### FIELD OF THE INVENTION

The present invention relates to a contact probe, and more particularly to a contact probe and a socket for testing semiconductor chips, in which each plunger is coupled to an elastic plate made of nonconductive material.

### BACKGROUND OF THE INVENTION

A chip is an integrated circuit that performs a variety of functions using logic elements fabricated on a thin small piece of semiconducting material, such functions being activated by electrical signals transmitted from a printed circuit board (PCB) through buses.

In general, a lot of chips are mounted in a variety of electronic products, and play an important role in determining the performance of each electronic product.

Further, the PCB is constructed so that a conductor, copper, is coated on a thin board made of an insulator, such as epoxy resin or bakelite resin, thereby forming circuit wiring. The PCB has electric/electronic elements such as integrated circuits, resistors, and switches soldered on the circuit wiring.

A microchip refers to a chip in which the electronic circuit of the PCB is integrated at high density. In order to check whether or not such a chip is normal before the chip is mounted on and assembled with the electronic product, the chip must be tested using test equipment.

In this test method, the chip is mounted on a socket device for testing. In order to test the chip in the socket without damage, a contact probe for testing semiconductor chips is mounted and used.

The socket for testing is mounted on a test PCB, and the microchip, which is the test target, is placed on the socket. Then, the test is performed. The socket for testing is mounted with a plurality of contact probes for testing semiconductor chips.

FIG. 1 is a sectional view illustrating a conventional contact probe for testing semiconductor chips.

As illustrated, the conventional contact probe includes an outer case 8, and a test probe needle 7 slidably installed in the outer case. A contact pin 6 is formed at a lower end of the outer case. A coil spring 9 is installed in the outer case, thereby supporting the probe needle.

When tested using this construction, the microchip is placed on the socket, and is pressed downward using a pressing unit installed on the socket. Thereby, the microchip is in contact with the probe needle of the contact probe.

However, this conventional contact probe has various problems in that the contact resistance thereof is great because electric current applied to the probe needle flows through the contact area between the outer case and the spring, in that the elastic force of the spring is reduced by over-current, and in that a signal path of the applied current is increased, thus reducing test reliability.

Further, as the semiconductor chips have recently been miniaturized with the development of integrated technology, the interval between lead terminals has been greatly narrowed, and thus the contact probe testing the chips has been required to be miniaturized. Therefore, the method of providing the elastic force to the test contact probe using the elastic spring has reached a limitation.

In order to improve this contact probe, a proposal for using a conductive spring or a conductive silicon unit was made in Korean Patent Application No. 10-2001-0075606, Patent No. 03127404 and so on.

Further, Korean Patent Application No. 10-2006-0075667, which was filed by the applicant of the present invention, proposed a contact probe for testing semiconductor chips in which a probe section is integrally formed with an elastic section.

However, these conventional technologies are unsuitable for miniaturization required for the test equipment of a highly integrated circuit resulting from technical development, and make the production and assembly of each element difficult due to structural complexity thereof.

### SUMMARY OF THE INVENTION

Accordingly, the present invention has been made keeping in mind the above problems occurring in the prior art, and an object of the present invention is to provide a contact probe and socket for testing semiconductor chips, which employs a simple structure that is easily manufactured, and reduces a signal path, thus improving test reliability.

Another object of the present invention is to provide a contact probe for testing semiconductor chips, in which the dimensions of test equipment are remarkably reduced.

In order to achieve the above object, according to the present invention, there is provided a contact probe for testing semiconductor chips, which comprises: a nonconductive elastic plate having main through-holes corresponding to contact terminals of a test target; plungers coupled on upper sides of the main through-holes, each having a plunger head that is elastically supported by the elastic plate and a plunger body that extends downwards from the center of the plunger head; and contact pins coupled on lower sides of the main through-holes, each having a receiving hole contacting the plunger body of each plunger at a center thereof.

Here, the receiving hole of each contact pin may pass through the bottom of each contact pin, and the plunger head may have a first flange formed on the outer circumference thereof, and the upper recess may be provided with a first hook step, so that the first flange may be confined by the first hook step.

Further, the first flange may protrude from the outer circumference of the plunger head in a continuous ring shape.

Furthermore, each contact pin may be placed in a lower recess formed in a lower portion of each main through-hole.

Also, each contact pin may have a second flange formed on the outer circumference thereof, and the lower recess may be provided with a second hook step, so that the second flange may be confined by the second hook step. Furthermore, each contact pin may be made of at least one of metal and conductive rubber, and the second flange may protrude from the outer circumference of each contact pin in a continuous ring shape.

Each plunger may be coupled to each contact pin with an elastic member interposed therebetween. Further, the elastic member may include a compression coil spring installed between the outer circumference of the plunger body and the inner circumference of each main through-hole, and the compression coil spring may be in contact with the bottom of the plunger head and the top of each contact pin at opposite ends thereof, respectively.

Here, the elastic plate may include elastic auxiliary through-holes, each of which is located between the nearest four main through-holes. Further, each elastic auxiliary through-hole may have a diameter less than that of each main through-hole.

Also, the receiving hole may have a seat formed on the inner circumference thereof, the seat having a washer placed thereon so as to elastically support the lower portion of the plunger body, and test electric current applied to the test target may flow from the plunger head of each plunger to each contact pin through each washer.

Furthermore, each washer may comprise: a circular plate placed on the seat; a plurality of cutout slots formed in the circular plate in a diametrical direction; and a plurality of elastic segments defined by the cutout slots, or may comprise: a circular plate placed in the receiving hole; and a plurality of elastic segments protruding from the outer circumference to the center of the circular plate.

Here, each elastic segment may protrude downwards from the outer circumference at a predetermined inclined angle.

Further, each washer may be fixed to each contact pin by bending the upper end of each contact pin in an inward radial direction.

Also, the plunger body may include a conical tip formed in the lower end thereof, which is in contact with each washer.

According to another aspect of the present invention, there is provided a contact socket for testing semiconductor chips, in which a contact probe is fixed to a base plate.

### BRIEF DESCRIPTION OF THE DRAWINGS

The above and other objects, features and other advantages of the present invention will be more clearly understood from the following detailed description when taken in conjunction with the accompanying drawings, in which:

FIG. 1 is a sectional view illustrating a conventional contact probe for testing;

FIG. 2 is a sectional view illustrating a contact probe for testing semiconductor chips according to an exemplary embodiment of the invention;

FIG. 3 illustrates a plunger and a contact pin according to an exemplary embodiment of the invention, in which FIG. 3(a) is a sectional view of the plunger, and FIG. 3(b) is a front view of the contact pin;

FIG. 4 is a perspective view illustrating a contact socket for testing semiconductor chips according to an exemplary embodiment of the invention;

FIG. 5 is a front view of FIG. 4;

FIG. 6 is a plan view illustrating an elastic plate, part of which is enlarged, according to an exemplary embodiment of the invention;

FIG. 7 is a sectional view illustrating a contact probe for testing semiconductor chips according to another exemplary embodiment of the invention;

FIG. 8 illustrates a contact probe for testing semiconductor chips according to another exemplary embodiment of the invention, in which FIGS. 8(a) and 8(b) are exploded perspective views, and FIG. 8(c) is an exploded sectional perspective view; and

FIG. 9 is a perspective view illustrating a washer according to another exemplary embodiment of the invention.

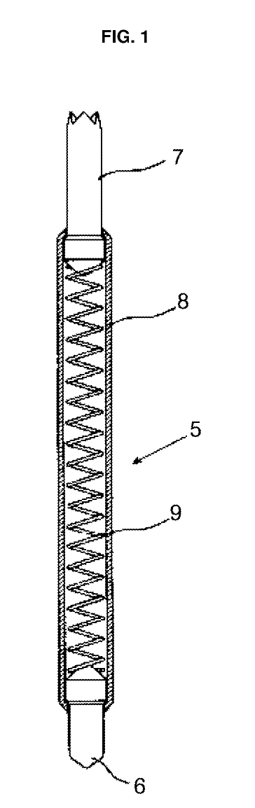

### DETAILED DESCRIPTION OF THE INVENTION

A contact probe and socket for testing semiconductor chips according to an exemplary embodiment of the invention will now be described in greater detail with reference to the accompanying drawings.

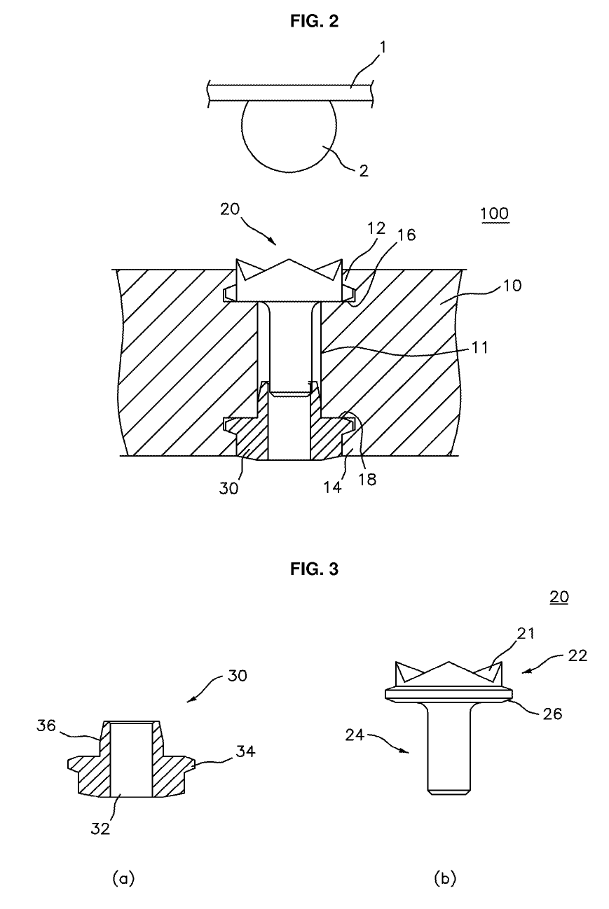

FIG. 2 is a sectional view illustrating a contact probe for testing semiconductor chips according to an exemplary embodiment of the invention. FIG. 3 illustrates a plunger and a contact pin according to an exemplary embodiment of the invention, in which FIG. 3(a) is a sectional view of the plunger, and FIG. 3(b) is a front view of the contact pin.

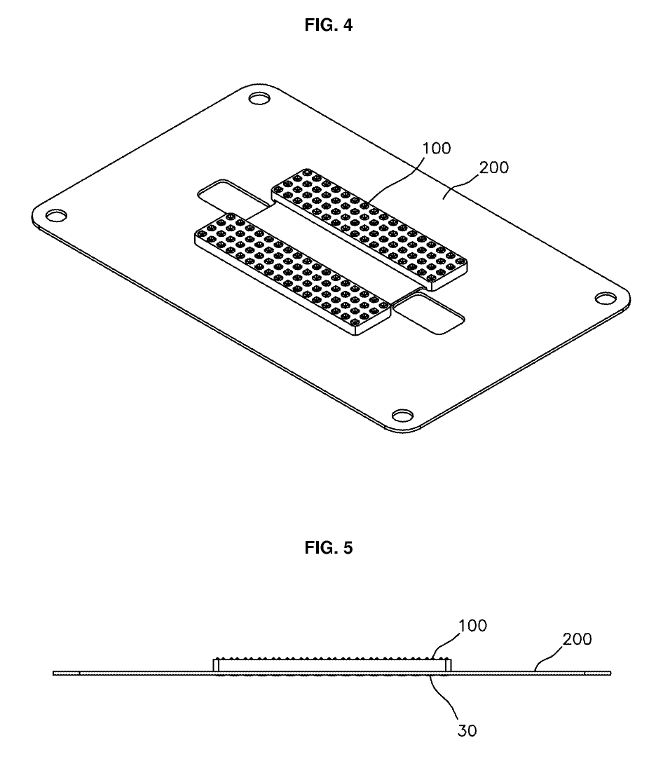

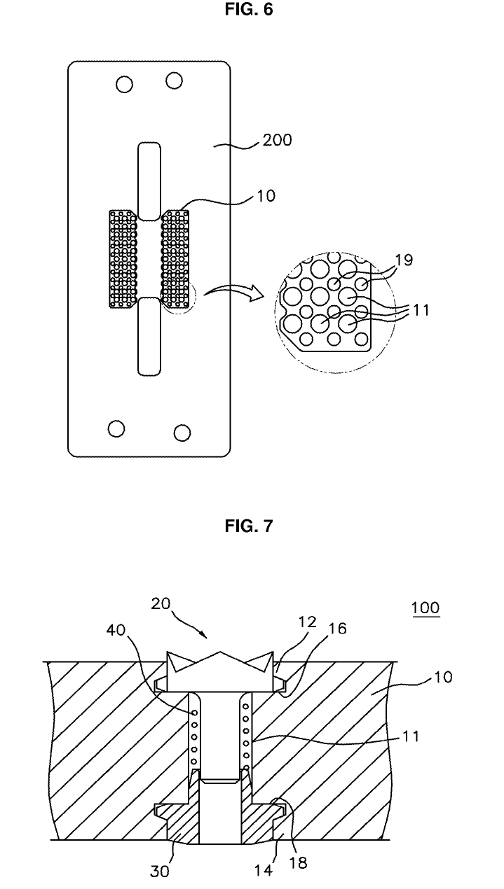

FIGS. 4 and 5 are a perspective view and a front view illustrating a contact socket for testing semiconductor chips according to an exemplary embodiment of the invention, respectively. FIG. 6 is a plan view illustrating an elastic plate, part of which is enlarged, according to an exemplary embodiment of the invention.

As illustrated in FIG. 2, the contact probe for testing semiconductor chips comprises plungers 20 brought into contact with contact terminals of a test target 1, an elastic plate 10, and contact pins 30. An elastic member can be interposed between each plunger 20 and each contact pin 30.

The elastic plate 10 has the shape of a flat plate, is provided with main through-holes 11 corresponding to the contact terminals 2 of the test target 1, and is made of nonconductive material.

Further, the elastic plate 10 is made of highly elastic material, such as rubber, silicon, or the like, serves to provide elastic force to each plunger 20, and is attached to a base plate 200 of nonconductive material such as Flame Resistant 4 (FR-4), as illustrated in FIG. 4.

Each main through-hole 11 is preferably provided with an upper recess 16 in an upper portion of which each plunger 20 is placed, and a lower recess 18 in a lower portion of which each contact pin 30 is placed.

Preferably, each of the upper and lower recesses 16 and 18 has an area wider than that of each main through-hole 11 when viewed from the top or the bottom, and is recessed into the elastic plate.

Next, each plunger 20 will be described.

Each plunger 20 includes a plunger head 22, which is provided, at the top thereof, with a probe needle 21 brought into contact with each contact terminal 2 of the test target 1, is coupled at an upper side of each main through-hole 11, and is elastically supported by the elastic plate 10, and a plunger body 24 that extends downwards from the center of the plunger head 22.

The plunger head 22 is preferably constructed such that it is placed in the upper recess 16 formed in the upper portion of each main through-hole 11, and such that a first flange 26 formed on the outer circumference of the plunger head 22 is confined in the first hook step 12 formed in the upper recess 16.

Preferably, the first flange 26 protrudes from the outer circumference of the plunger head 22 in a continuous ring shape, and the first hook step 12 protrudes from the upper portion of the upper recess 16 toward the center of each main through-hole 11, so that the first flange 26 is firmly fixed to the elastic plate 10.

Further, the plunger body 24 serves to allow test electric current to flow from the plunger head 22 to the contact pin 30, a detailed description of which will be made below.

Each plunger 20 is preferably made of a beryllium-copper alloy, which has high strength and corrosion resistance and is produced by adding beryllium of 3% or less by weight, and a small quantity of cobalt, silver, and nickel to copper.

Next, each contact pin 30 will be described.

Each contact pin 30 serves to allow the test electric current to flow from the plunger 20 to a printed circuit board (PCB). Each contact pin 30 is provided with a receiving hole 32 in the center thereof, and is coupled at a lower side of each main through-hole 11, and is preferably placed in the lower recess 18 formed in the lower portion of each main through-hole 11.

As illustrated in FIG. 3, each contact pin 30 is provided, at an upper portion thereof, with a close-contact part 36, which protrudes upwards so that is easily comes into contact with each plunger 20 and is thus inserted into each main through-hole 11.

As the close-contact part 36 is formed at the upper portion of each contact pin, the length of the receiving hole 32 is increased. Thus, the plunger body 24 easily comes into contact with the contact pin 30.

Further, as illustrated in FIG. 3, the receiving hole 32 preferably passes through the contact pin 30.

As illustrated, the receiving hole 32 serves to guide the plunger body 24 when the plunger body 24 moves up and down, and is constructed not only to have a size corresponding to the outer circumference of the plunger body 24 such that the outer circumference of the plunger body 24 is in contact with the inner circumference of the receiving hole 32, but also to partially receive the lower portion of the plunger body 24.

Further, a second flange 34 formed on the outer circumference of each contact pin 30 is preferably constructed to be confined in a second hook step 14 formed in the lower recess 18.

The second flange 34 protrudes from an outer circumference of each contact pin 30 in a continuous ring shape, and the second hook step 14 protrudes from the lower recess 18 toward the center of each main through-hole 11, so that the second flange 34 is firmly fixed to the elastic plate 10.

As described above, when in contact with the test target, each plunger 20 moves up and down according to the load from the test target. Thus, the plunger body 24 moves up and down in the receiving hole 32. At this time, the inner circumference of the receiving hole 32 is preferably constructed such that it is in contact with the outer circumference of the plunger body, so that the test electric current flows to the contact pin 30.

Each contact pin 30 is preferably made of metal such as a beryllium-copper alloy, which is the same material as each plunger or conductive rubber material, so that it is able to assist the elastic force of the elastic plate 10.

Now, each elastic member will be described.

Each elastic member is interposed between each plunger and each contact pin, and serves to assist the elastic force of the elastic plate 10. As illustrated in FIG. 7, each elastic member is preferably interposed between each plunger and each contact pin in each main through-hole 11.

As illustrated in FIG. 2, each elastic member, such as each compression coil spring 40, is preferably inserted in a predetermined space between the outer circumference of the plunger body 24 and the main through-hole 11 such that respective opposite ends thereof are in contact with the bottom of the plunger head 22 and the top of the contact pin 30.

As illustrated in FIGS. 4 and 5, a contact socket for testing semiconductor chips is constructed by coupling the above-mentioned contact probe 100 to a base plate 200. As illustrated in FIG. 5, each contact pin 30 is preferably constructed such that the lower portion thereof protrudes from the bottom of the base plate 200 and is electrically connected to the PCB for testing.

Further, as illustrated in FIG. 6, the elastic plate 10 is preferably provided with elastic auxiliary through-holes 19, each of which is located between the four nearest main through-holes 11, so as to be easily deformed by a vertical load generated when each plunger comes into contact with the test target, to thereby assist the elastic force of the elastic plate 10.

Preferably, each elastic auxiliary through-hole 19 has a diameter smaller than that of each main through-hole 11 so that it is able to prevent the elastic plate 10 from being damaged by the repeated elastic deformation.

Now, the contact probe for testing semiconductor chips according to another embodiment of the invention will be described.

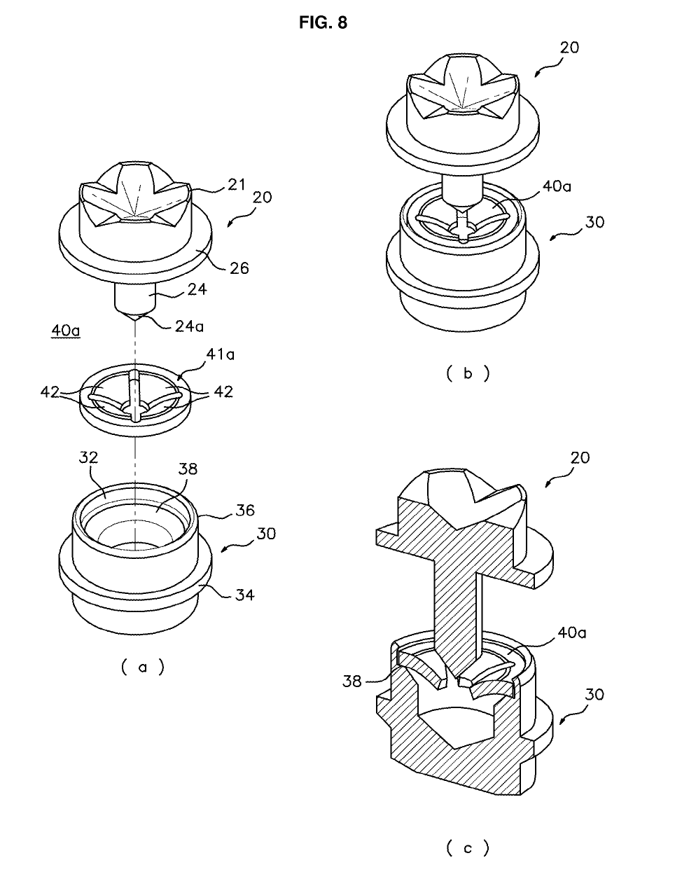

FIG. 8 illustrates a contact probe for testing semiconductor chips according to another exemplary embodiment of the invention, in which FIGS. 8(a) and 8(b) are exploded perspective views, and FIG. 8(c) is an exploded sectional perspective view.

As illustrated in FIG. 8, the contact probe for testing semiconductor chips includes washers 40a, each of which is placed on a seat 38 formed in the inner circumference of the receiving hole 32 of each contact pin and elastically supports the lower portion of the plunger body 24 of each plunger. Thereby, the test electric current can flow from the plunger 20 to the contact pin 30 through the washer 40a.

The washer 40a preferably comprises a circular plate 41a placed in the receiving hole 32, and a plurality of elastic segments 42 protruding from the outer circumference to the center of the circular plate 41a.

Preferably, the elastic segments 42 protrude downwards from the inner circumference of the circular plate 41a at a predetermined inclined angle such that the lower end of the plunger body 24 can easily move down.

Further, as illustrated in FIG. 8(b), the washer 40a is fixed to the contact pin 30 by bending the upper end of the contact pin 30 in an inward radial direction. Thereby, the washer 40a is adapted to be in contact with the plunger body 24 so that a test can be stably performed.

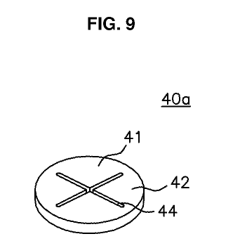

FIG. 9 is a perspective view illustrating a washer according to another exemplary embodiment of the invention.

As illustrated, the washer 40a functions to assist the elastic force of the elastic plate 10, and preferably comprises a circular plate 41 placed on the seat 38 of each contact pin, a plurality of cutout slots 44 formed in the circular plate 41 in a diametrical direction, and a plurality of elastic segments 42 defined by the cutout slots 44.

Preferably, the plunger body 24 is provided with a conical tip 24a at the lower end thereof which is in contact with the washer 40a such that the washer 40a is easily brought into contact with the plunger 20.

Hereinafter, a method of fabricating the contact probe and socket for testing semiconductor chips according to the invention will be described.

In order to fabricate the contact probe for testing semiconductor chips, an elastic plate, which is made of rubber and has a preset standard, has formed therein a plurality of main through-holes, each of which has upper and lower recesses, and first and second hook steps, at regular intervals. The upper and lower recesses of each main through-hole are pressed by the respective plunger and contact pin. Thereby, the first and second hook steps of the respective main through-hole confine a first flange of the respective plunger and a second flange of the respective contact pin.

When the plungers and the contact pins are coupled and fixed to the elastic plate, the lower outer circumference of the plunger body of each plunger is adapted to be in partial contact with the upper inner circumference of a receiving hole of each contact pin.

Further, in the case in which the contact probe requires great elastic force, a compression coil spring can be installed in each main through-hole, or each contact pin can be made of conductive rubber so as to exert required elastic force.

Alternatively, the elastic plate may be provided with a plurality of elastic auxiliary through-holes between the main through-holes so as to increase the elastic force thereof, or a washer may be interposed between each plunger and each contact pin so as to assist the elastic force of the elastic plate.

Especially, in the case in which each washer is interposed, test electric current has to flow from a plunger head to the plunger body of each plunger, each washer, and each contact pin in turn.

The contact probe for testing semiconductor chips according to the invention is coupled to a base plate of nonconductive material, and thus a contact socket for testing semiconductor chips is completed. The contact socket is mounted on a PCB for testing, and then a test target such as a microchip is placed on the contact socket. Then, the testing of the test target is performed.

The test electric current applied to the microchip flows from the plunger head to each contact pin through the plunger body. Continuously, the test electric current flows to the PCB for testing. Thereby, the microchip is tested with respect to whether or not it operates normally.

In this process, the load generated by the contact with the test target is elastically supported by the elastic plate. When the elastic plate is deficient in elastic force, the compression coil spring or the washer can be installed between each plunger and each contact pin, or the contact pin can be made of elastic material.

Further, in this process, the plunger head of each plunger and each contact pin are provided with the first and second flanges on the outer circumferences thereof, respectively, such that the plungers and the contact pins are firmly fixed to the elastic plate. Thereby, the first and second flanges are confined by the first and second hook steps formed in the upper and lower recesses of each main through-hole of the elastic plate.

As can be seen from the foregoing, the contact probe and socket for testing semiconductor chips employ a simple structure in which each plunger is coupled in each main through-hole formed at the nonconductive elastic plate.

According to the invention, the contact probe and socket for testing semiconductor chips employ a simple structure capable of coupling the plungers to the nonconductive elastic plate and elastically supporting the plungers, so that they can be easily manufactured, and the test reliability can be obtained by reducing a signal path of the test electric current.

Further, the elastic plate providing the elastic force to each plunger is integrally manufactured, so that it can be manufactured at a subminiature size suitable for equipment for testing semiconductor chips that are gradually becoming complicated due to the technical development thereof.

The elastic plate is provided with the elastic auxiliary through-holes, and the elastic members or the washers are interposed between the plungers and the contact pins, so that the elastic plate can exert sufficient elastic force when in contact with the test target.

Although an exemplary embodiment of the invention has been described for illustrative purposes, those skilled in the art will appreciate that various modifications, additions and substitutions are possible, without departing from the scope and spirit of the invention as disclosed in the accompanying claims.

What is claimed is:

1. A contact probe for testing semiconductor chips, comprising:
a nonconductive elastic plate having main through-holes corresponding to contact terminals of a test target;
plungers coupled on upper sides of the main through-holes, each having a plunger head that is elastically supported by the elastic plate and a plunger body that extends downwards from a center of the plunger head; and
contact pins coupled on lower sides of the main through-holes, each having a receiving hole contacting the plunger body of each plunger at a center thereof.

2. The contact probe as set forth in claim 1, wherein the receiving hole of each contact pin passes through a bottom of each contact pin.

3. The contact probe as set forth in claim 1, wherein the plunger head is placed in an upper recess formed in an upper portion of each main through-hole.

4. The contact probe as set forth in claim 3, wherein: the plunger head has a first flange formed on an outer circumference thereof; the upper recess is provided with a first hook step; and the first flange is confined by the first hook step.

5. The contact probe as set forth in claim 4, wherein the first flange protrudes from the outer circumference of the plunger head in a continuous ring shape.

6. The contact probe as set forth in claim 1, wherein each contact pin is placed in a lower recess formed in a lower portion of each main through-hole.

7. The contact probe as set forth in claim 6, wherein: each contact pin has a second flange formed on an outer circumference thereof; the lower recess is provided with a second hook step; and the second flange is confined by the second hook step.

8. The contact probe as set forth in claim 7, wherein the second flange protrudes from the outer circumference of each contact pin in a continuous ring shape.

9. The contact probe as set forth in claim 1, wherein each contact pin is made of at least one of metal and conductive rubber.

10. The contact probe as set forth in claim 1, wherein each plunger is coupled to each contact pin with an elastic member interposed there between.

11. The contact probe as set forth in claim 10, wherein the elastic member includes a compression coil spring installed between an outer circumference of the plunger body and an inner circumference of each main through-hole, and the compression coil spring is in contact with a bottom of the plunger head and a top of each contact pin at opposite ends thereof, respectively.

12. The contact probe as set forth in claim 1, wherein the elastic plate includes elastic auxiliary through-holes, each of which is located between four nearest main through-holes.

13. The contact probe as set forth in claim 12, wherein each elastic auxiliary through-hole has a diameter less than that of each main through-hole.

14. The contact probe as set forth in claim 1, wherein: the receiving hole has a seat formed in an inner circumference thereof; the seat has a washer placed thereon so as to elastically support a lower portion of the plunger body; and test electric current applied to the test target flows from the plunger head of each plunger to each contact pin through each washer.

15. The contact probe as set forth in claim 14, wherein each washer comprises:
a circular plate placed on the seat;
a plurality of cutout slots formed in the circular plate in a diametrical direction; and
a plurality of elastic segments defined by the cutout slots.

16. The contact probe as set forth in claim 14, wherein each washer comprises:
a circular plate placed in the receiving hole; and
a plurality of elastic segments protruding from an outer circumference to a center of the circular plate.

17. The contact probe as set forth in claim 16, wherein each elastic segment protrudes downwards from the outer circumference at a predetermined inclined angle.

18. The contact probe as set forth in claim 14, wherein each washer is fixed to each contact pin by bending an upper end of each contact pin in an inward radial direction.

19. The contact probe as set forth in claim 14, wherein the plunger body includes a conical tip formed in a lower end thereof that is in contact with each washer.

20. A contact socket for testing semiconductor chips, characterized in that the contact probe as set forth in claim 1 is fixed to a base plate.
